(19) United States
(12) Patent Application Publication
(10) Pub. No.: US 2016/0105956 A1
(43) Pub. Date: Apr. 14, 2016

(54) PRINTED CIRCUIT BOARD AND METHOD OF FABRICATING THE SAME

(71) Applicant: SAMSUNG ELECTRO-MECHANICS CO., LTD., Suwon-si (KR)

(72) Inventors: Jun Oh HWANG, Hwaseong-si (KR); Kwang Hee KWON, Busan (KR); Seung Eun LEE, Seongnam-si (KR); Young Kwan LEE, Changwon-si (KR); Yul Kyo CHUNG, Yongin-si (KR); Se Rang IM, Suwon-si (KR); Ki Jung SUNG, Seoul (KR)

(73) Assignee: SAMSUNG ELECTRO-MECHANICS CO., LTD, Suwon-si (KR)

(21) Appl. No.: 14/877,291

(22) Filed: Oct. 7, 2015

(30) Foreign Application Priority Data
Oct. 8, 2014 (KR) 10-2014-0135848

(51) Int. Cl. H05K 1/02; H05K 3/06; H05K 3/46; H05K 3/00; H05K 1/11; H05K 1/03

(52) U.S. Cl. CPC H05K 1/0298; H05K 1/115; H05K 1/111; H05K 1/0313; H05K 3/4644; H05K 3/0064; H05K 3/06

(57) ABSTRACT

The present invention provides a printed circuit board includes an insulating member, a first plating layer buried in a bottom region of the insulating member, a second plating layer buried in a top region of the insulating member and a plating via for electrically connecting the first plating layer and the second plating layer by being buried in any one among the top region and the bottom region of the insulating member.

### CROSS-REFERENCE TO RELATED APPLICATIONS

This application claims the benefit under 35 U.S.C. Section 119 of Korean Patent Application Serial No. 10-2014-0135848, filed Oct. 8, 2014, which is hereby incorporated by reference in its entirety into this application.

### BACKGROUND

1. Field

The present invention relates to a printed; and, more particularly to a printed circuit board with a coreless structure and a method of fabricating the same.

2. Description of Related Art

As the printed circuit board (PCB) is to form the plating line of a circuit line pattern on an electrically insulation substrate, the printed circuit board has been also studied or developed for the multi-layer, the improvement of wiring density or the like according to the trends of the miniaturization, the slimness and the high density.

In order for forming the fine pattern of the printed circuit board and improving the reliability and the design density, the structure is changed into a complex configuration of the circuit layers together with the change of raw material; and, accordingly, the double side PCB to form the wirings on both sides or the multi-layer board to form the wirings in multi-layer has been widely used except the single PCB to form the wiring only on one side of the insulating substrate.

A conventional PCB forms the plating lines of the circuit line patterns on a top and bottom surfaces of the core layer, and has the structure formed in such a way that the via for connecting the plating layer of the top layer to the plating layer of the bottom layer penetrates the core layer. Accordingly, after the via hole to penetrate the core layer through a laser or a mechanical punching is fabricated and an inner wall of the via hole is plated as a pre-treatment process for plating the inside of the via hole, a tenting process for forming the plating layer thereon is performed, whereby the manufacturing process becomes complex. This acts as the factors to rise the manufacturing time and cost.

And also, in recent, since the flexibility has been required for the wearable products such as a smart watch and a smart glasses or the panel used for TV or the mobile phone, the demands for the flexible PCB becomes increased, in this result, in the above-described convention PCB, the flexibility becomes decreased due to the existence of the core layer.

### RELATED ART DOCUMENT

### Patent Document

Patent Document 1: Korean Patent Publication No. 2001-0065115

### SUMMARY

The present invention has been invented in order to overcome the above-described problems and it is, therefore, an object of the present invention to provide a printed circuit board without having a core layer as a structure that a plating layer is buried in an insulating member and with a structure that a plating via to connect a top and a bottom plating layers are buried together.

In accordance with a first embodiment of the present invention to achieve the object, there is provided a printed circuit board including an insulating member where a first plating layer and a second plating layer are buried, wherein a first plating layer buried in a bottom region of the insulating member and a second plating layer buried in a top region of the insulating member.

Herein, the first plating layer is buried in a bottom region of the insulating member where the first plating layer is buried, i.e., the first insulating member, with the same thickness of the first insulating member, and the second plating layer is buried in a top region of the insulating member where the second plating layer is buried, i.e., the second insulating member, with the same thickness of the second insulating member. Accordingly, the present invention does not have a core layer between the first plating layer and the second plating layer and can supply the printed circuit board to be insulated between the first plating layer and the second plating layer by alternately arranging the first plating layer and the second plating layer at each of the dedicated periods divided in a longitudinal direction.

In a method of fabricating a printed circuit board of the present invention, to achieve the object, there is provided a plating via to connect a first plating layer and a second plating layer arranged in a diagonal line direction is formed with the first plating layer and the second plating layer at the same time with one plating process; and, accordingly, the present invention provides the printed circuit board made of one metal to form the plating via and the first plating layer and the second plating layer which are connected through the plating via in a body.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a printed circuit board in accordance with one embodiment of the present invention; and

FIG. 2 to FIG. 11 are process cross-sectional views showing a method of fabricating a printed circuit board in accordance with another embodiment of the present invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

On the other hands, for simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

Hereinafter, the configurations and operational effects of the present invention will be described in detail with reference to the accompanying drawings so that those skilled in the art can easily practice the present invention.

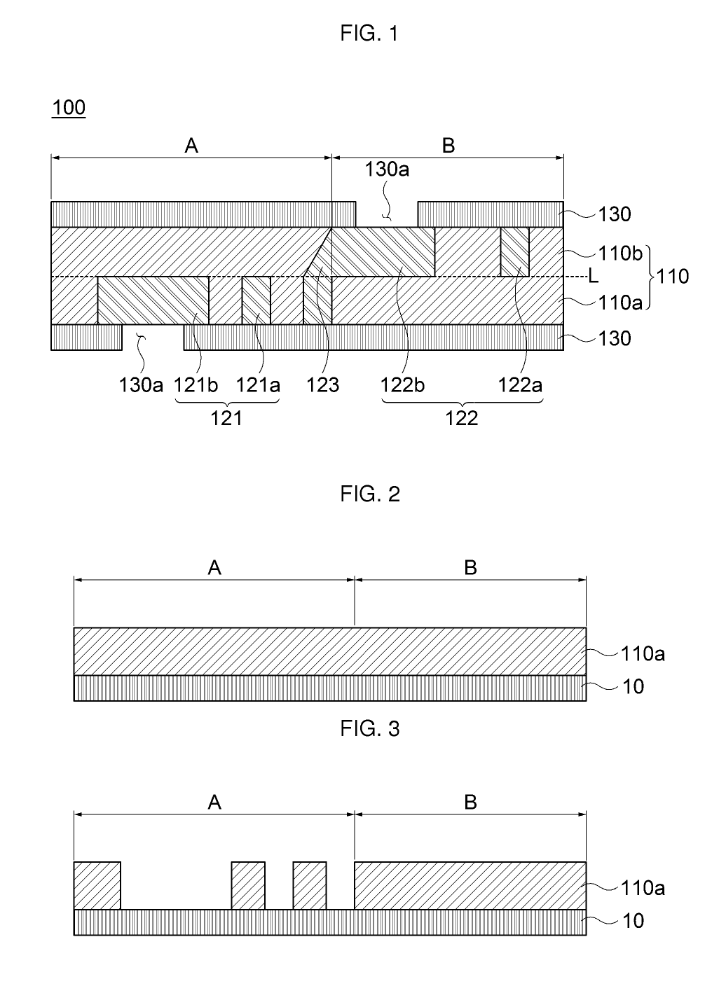

FIG. 1 is a cross-sectional view showing a printed circuit board in accordance with one embodiment of the present invention.

Referring to FIG. 1, a printed circuit board 100 in accordance with the embodiment of the present invention includes an insulating member 110 and a first plating layer 121 and a second plating layer 122 buried in the insulating member 110.

The first and the second plating layers 121 and 122 include a pair of circuits 121a and 122a to be a signal transfer line and a pair of pads 121b and 122b formed with a width wire than the circuits 121a and 122a for the connection reliability with the external chips. Accordingly, the first and the second plating layers 121 and 122 are made of at least one material selected from a group consisting of Ag with excellent electrical conductivity, Pd, Al, Ni, Ti, Au, Cu or Pt or the mixture obtained by mixing at least two thereof.

Since the first and the second plating layers 121 and 122 are formed by plating the metal material between the patterns formed in the insulating member 110, the insulating member 110 is made of photosensitive resin so as to allow the photolithography process to be perform for forming the patterns.

And also, since the insulating member 110 can insulate between the patterns of the first and the second plating layers 121 and 122, and plays the role of protecting the first and the second plating layers 121 and 122 from the outside, it is preferable that the constitution material of the insulating member 110 is selected considering on the insulating property, heat resistance, water tolerance or the like. For example, the optimum polymer material to form the insulating member 110 can be a thermosetting resin such as an epoxy resin, a thermoplastic resin such as a polyimide or a resin (prepreg) in which a stiffener such as a glass fiber or an inorganic filler is impregnated.

Particularly, the insulating member 110 is classified into a top region above a dotted line L and a bottom region below the dotted line L with reference to the virtual dotted line parallel to a thickness direction with passing through the center of the insulating member 110. Herein, the explanation that the dotted line L is passed through the center of the insulating member 110 is only one example, the insulating member 110 may be divided with reference to the top side or the bottom side of the dotted line L shown in the drawing.

In such structure, the first plating layer 121 is buried in the bottom region of the insulating member 110 and the second plating layer 122 is buried in the top region of the insulating member 110. That is, if the bottom region where the first plating layer 121 is buried is called as a first insulating member 110a and the top region where the second plating layer 122 is buried is called as a second insulating member 110b, the first plating layer 121 is buried in the first insulating member 110a by being formed in the bottom surface of the second insulating member 110b and the second plating layer 122 is buried in the second insulating member 110b by being formed in the top surface of the first insulating member 110a.

Herein, since the first insulating member 110a and the second insulating member 110b are individually formed in the manufacturing process, an interface can be formed between the first insulating member 110a and the second insulating member 110b. Merely, after the second insulating member 110b made of the same material of the first insulating member 110a is stacked on the first insulating member 110a, it is pressed and sintered; and, the first insulating member 110a and the second insulating member 110b can be unified not to discriminate the interface therebetween. Accordingly, in the drawing, there is shown one insulating member 110 formed by coupling the first insulating member 110a and the second insulating member 110b without an additional interface.

The first plating layer 121 is buried in the same thickness of the first insulating member 110a, and the second plating layer 122 is also buried in the same thickness of the second insulating member 110b. Accordingly, the total thickness of the insulating member 110 is matched to the thickness obtained by summing the thickness of the first plating layer 121 and the thickness of the second plating layer 122. Since such structure is obtained by forming the first plating layer 121 and the second plating layer 122 with one plating process at the same time, the explanation for this will be described in detail in the manufacturing method of the present invention.

Like this, the printed circuit board 100 of the present invention does not have an additional core layer between the first plating layer 121 and the second plating layer 122, since the first and the second plating layers 121 and 122 are buried in the insulating member 110, the total thickness of the substrate can be drastically reduced in comparison with the printed circuit board that the circuit patterns are protruded and formed on the top and the bottom surfaces of the core layer as like the conventional method.

And also, according to the such buried structure, since the first plating layer 121 and the second plating layer 122 are stably fixed to the insulating member 110, even in the flexible PCB requiring to the flexibility, the failure of the patterns of the first and the second plating layers 121 and 122 can be prevented as well as the risk of short between the patterns can be minimized.

On the other hands, the insulating between the first plating layer 121 and the second plating layer 122 can be performed with the arrange structure of the first and the second plating layers 121 and 122. That is, the first plating layer 121 and the second plating layer 122 are alternately arranged on the first insulating member 110a and the second insulating member 110b around the plating via 123.

For example, as shown in the drawings, assuming that the substrate is divided into an A period and a B period along a length direction, the first plating layer 121 is formed at the A period and the second plating layer 122 is formed at the B period. Like this, if the first plating layer 121 and the second plating layer 122 are alternately arranged at the dedicated period divided along the lengthwise direction, they are insulated without being in contact with each other.

And, the electrical connection between the first plating layer 121 and the second plating layer 122 is performed through the plating via 123 buried any one among the first insulating member 110a and the second insulating member 110b. As like the above, since the first plating layer 121 and the second plating layer 122 are arranged by being divided at the dedicated periods respectively, the plating via 123 can connect the outermost pattern adjacent to the B period at the first plating layer 121 to the outermost pattern adjacent to the A period at the second plating layer 121.

Like this, as the plating via 123 connects the first plating layer 121 and the second plating layer 122 arranged in the diagonal direction, the bottom surface of the plating via 123 is in contact with the first plating layer 121 and one side surface is in contact with the second plating layer 122. And, the other side surface of the plating via 123 which is not in contact with the first and the second plating layers 121 and 122 is buried in the insulating member 110 in the inclined shape.

Since the fact that the plating via 123 is formed with such structure is that the plating via 123 is formed with the first and the second plating layers 121 and 122 at the same time, accordingly, the plating via 123 and the first and the second plating layers 121 and 122 connected through the plating via 123 are formed with one metal in a body without an additional interface therebetween.

Although the plating via 123 in the drawing is shown to connect the circuit 121a of the first plating layer 121 to the pad 122b of the second plating layer 122, but it is not limited thereto, for example, it is possible that the pad 121b of the first plating layer 121 is connected to the circuit 122a of the second plating layer 122 or the circuit 121a of the first plating layer 121 is connected to the circuit 122a of the second plating layer 122, or the connection of various

And also, although the plating via 123 is shown to be buried in the second insulating member 110b, it can be changed according to the stacking order of the first plating layer 121 and the second plating layer 122. For example, in case when the second plating layer 122 is arranged at the bottom region of the insulating member 110 different from the drawings, the plating via 123 may be buried in the first insulating member 110a where the first plating layer 121 is buried.

The printed circuit board 100 of the present invention can further include an external insulating member 130 stacked on the top and the bottom surfaces of the insulating member 110 in order to protect the first plating layer 121 and the second plating layer 122 from the outside. Accordingly, the top side of the first plating layer 121 is covered by the second insulating member 110b and the bottom side is covered by the external insulating layer 130 to thereby being protected from the outside. And, the top side of the second plating layer 122 is covered by the external insulating layer 130 and the bottom side is covered by the first insulating member 110a to thereby being protected from the outside.

In the external insulating layer 130, the opening units 130a are formed to expose the pad regions of the first and the second plating layers 121 and 122, and the solder bump (not shown in the drawings) is formed thereon, whereby the printed circuit board 100 of the present invention may be connected to the external chips.

Now, a method of fabricating a printed circuit board of the present invention will be explained in detail.

FIG. 2 to FIG. 11 are process cross-sectional views showing a method of fabricating a printed circuit board in accordance with another embodiment of the present invention.

Referring to FIG. 2 to FIG. 11, the method of fabricating the printed circuit board of the present invention performs a patterning step to form the pattern by selectively etching a predetermined period of the first insulating member 110a (FIG. 3), after preparing the first insulating member 110a made of a photosensitive resin as the first step (FIG. 2).

Herein, the first insulating member 110a may be prepared at the state to be stacked on the carrier 10. The carrier 10 functions as a supporting member, since after the following processes it is separated from the first insulating member 110a; and, it is preferable that the material of the carrier 10 is the metal material capable of being easily separated from the first insulating member 110a and having an excellent rigidity.

The patterning step can be performed through the photolithography process, and it is proceeded at a predetermined interval, e.g., only the period A, of the first insulating member 110a. That is, the patterned A period is the period that the first plating layer 121 is formed, and the not-patterned B period is the period that the second plating layer 122 is formed.

Accordingly, the patterning step exposes after arranging the photo mask (not shown in the drawings) formed thereon the patterns corresponding to the circuits 121a and the pads 121b constituting the first plating layer 121 on the first insulating member 110a, and removes the remaining region except the portion hardened by being exposed to the light continuously, i.e., the portion where the circuits 121a and the pads 121b are formed, with the developer.

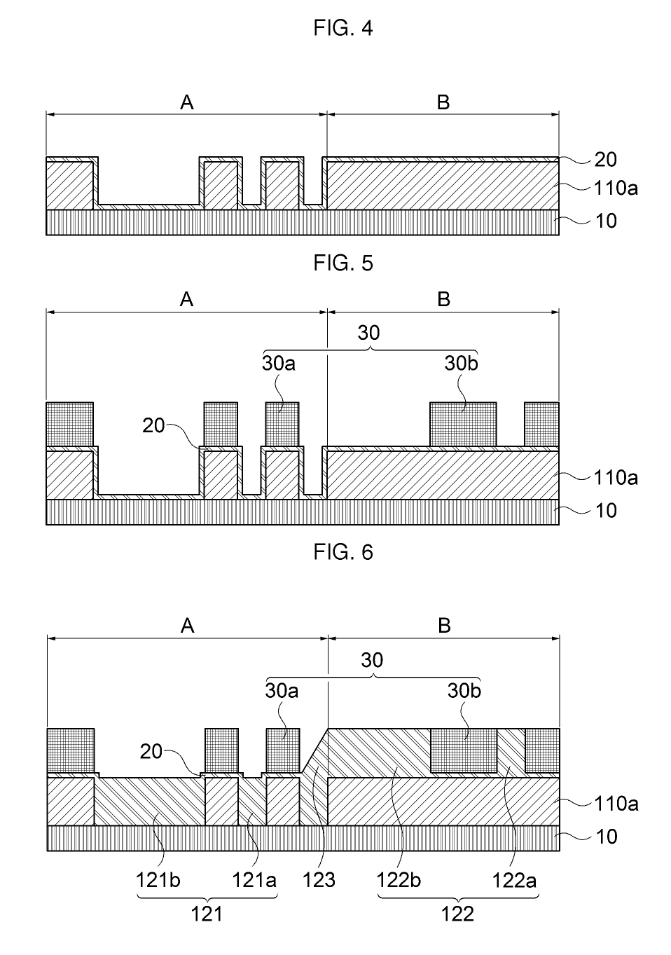

Thereafter, the step of forming the seed layer 20 on the surface of the first insulating member 110a formed thereon the patterns are proceeded (FIG. 4).

As the step of forming the seed layer 20 is a pretreatment process to perform the following electroplating process, after depositing the first insulating member 110a formed thereon the patterns into the copper plating tank, if applies the current, the copper is separated from the plating solution. In this results, the seed layer 20 is formed on the whole surface of the first insulating member 110a including the inner wall and the bottom surface of the patterns.

Thereafter, a step of arranging the resist pattern on the first insulating member 110a is performed (FIG. 5).

The resist pattern 30 includes a first resist pattern 30a arranged at the patterned A period in the first insulating member 110a and a second resist pattern 30b arranged at the not-patterned B period.

Since the second plating layer 122 is formed by filling the metal between the second resist patterns 30b, the second resist pattern has the pattern corresponding to the circuits 122a and the pads 122b which form the second plating layer 122. And, as the first resist pattern 30a is to prevent the plating from being performed above the pattern of the first insulating member 110a, it is formed with the same pattern of the first insulating member 110a.

Thereafter, the plating process is performed to perform the electroplating by using the seed layer 20 as a lead line and to grow the metal material between the patterns of the first insulating member 110a and between the resist patterns (FIG. 6).

As results of the plating process, in the A period, the first plating layer 121 is formed between the patterns of the first insulating member 110a; and, in the B period, the second plating layer 122 is formed together between the second resist pattern 30b at the same time. And, at the region adjacent to the matching point between the A period and the B period, the plating via 123 to connect the first plating layer 121 and the second plating layer 122 is naturally formed. Herein, for the convenience of the explanation, the seed layer 20 at the bottom portions of the first plating layer 121 and the second plating layer 122 is not shown by being additionally divided, it is shown by being included into the first and the second plating layers 121 and 122.

Like this, in the present invention, the first plating layer 121 and the second plating layer 122 are formed at the same time with one plating process without an individual process, since the plating via 123 to connect the first plating layer 121 and the second plating layer 122 are also naturally formed in the plating processes of the first and the second plating layers 121 and 122, the present invention can reduce the manufacturing time and cost drastically in comparison with a conventional method.

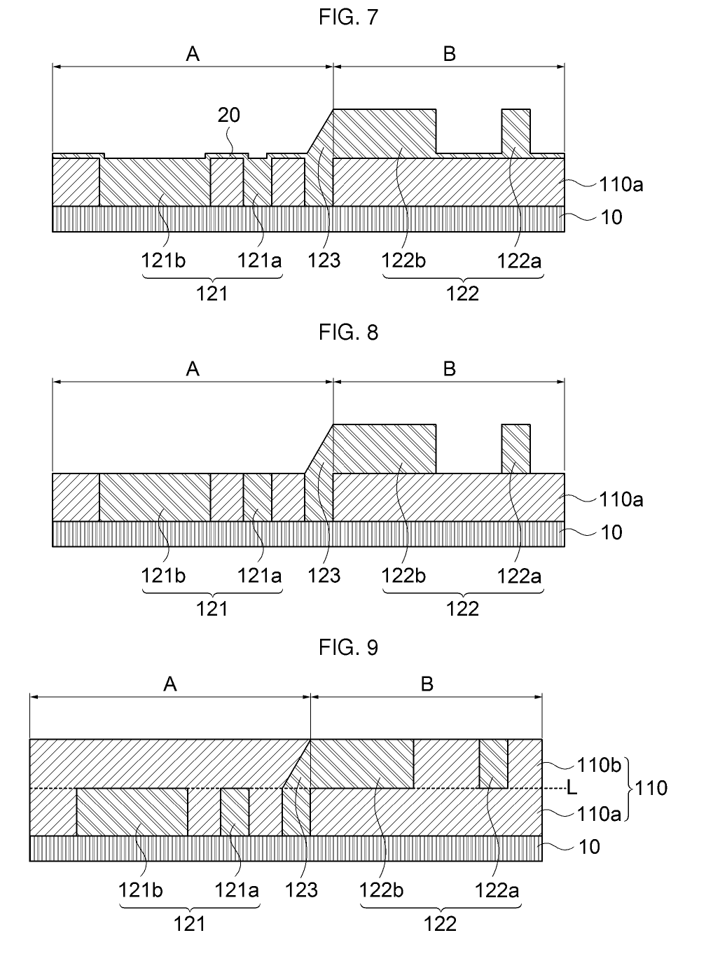

After finishing the plating process, the resist pattern 30 is delaminated (FIG. 7), the seed layer 20 exposed to the outside is removed through the flash etching or the soft etching (FIG. 8).

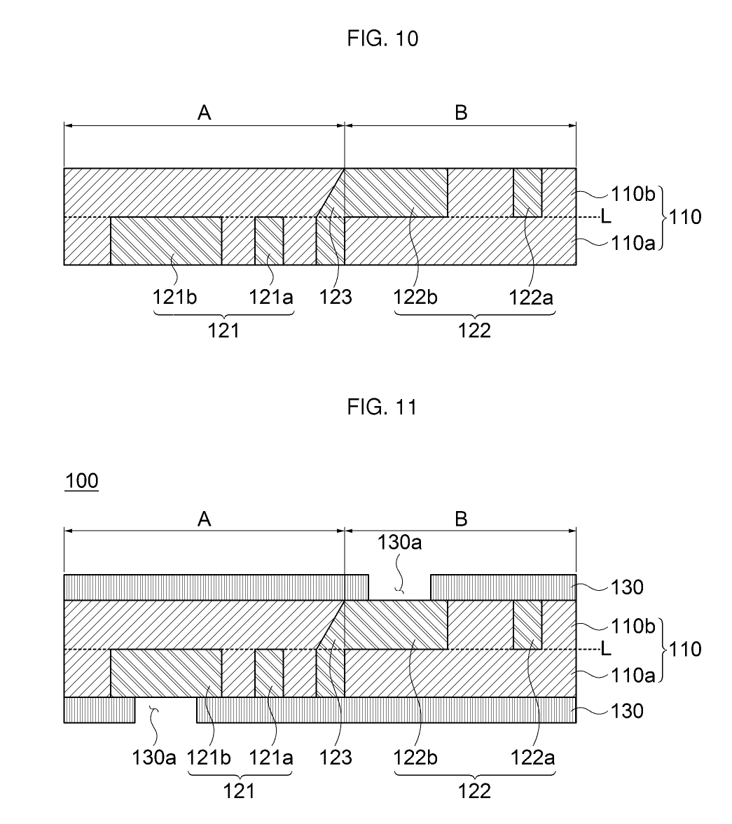

Thereafter, the second insulating member 110b is coated on the first insulating member 110a (FIG. 9), if the carrier is removed, the printed circuit board of the present invention is finally finished (FIG. 10). Herein, since the second insulating member 110b is made of the same material of the first insulating member 110a, it is unified with the first insulating member 110a by being pressed and sintered after the coating.

In addition, in order for protecting the first and the second plating layers 121 and 122, the external insulating layer 130 is further stacked on the external layers of the first insulating member 110a and the second insulation member 110b, and the opening member 130a can be fabricated on the external insulating layer 130 to expose the pad regions.

In accordance with the printed circuit board of the present invention, the overall thickness of the substrate is drastically reduced in comparison with the printed circuit board formed to protrude the circuit pattern at the top and the bottom surface of the a conventional core layer; and, in this result, it can secure the high reliability in the flexible substrate to require a flexibility.

And also, in accordance with the printed circuit board of the present invention, the pattern failure of the plating layer is prevented in the flexible substrate by stably fixing the plating layer to the insulating member, and can minimizing the risk of short between the patterns.

And also, in accordance with the method of fabricating the printed circuit board of the present invention, the top side plating layer and the bottom side plating layer are formed at the same time by one plating process without an individual process, since the plating via is smoothly formed in the plating process to form the plating layer without performing the a conventional complex process, it can drastically reduce the manufacturing time and cost.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A printed circuit board comprising:
an insulating member;
a first plating layer buried in a bottom region of the insulating member;
a second plating layer buried in a top region of the insulating member; and
a plating via for electrically connecting the first plating layer and the second plating layer by being buried in any one among the top region and the bottom region of the insulating member.

2. The printed circuit board according to claim 1, wherein the plating via and the first plating layer and the second plating layer connected through the plating via are made of one metal in a body.

3. The printed circuit board according to claim 1, wherein a bottom surface of the plating via is in contact with the first plating layer, one side is in contact with the second plating layer and the other side not to be in contact with the first and the second plating layers is buried in the insulating member.

4. The printed circuit board according to claim 1, wherein a thickness of the insulating member is equal to a thickness obtained by summing a thickness of the first plating layer and a thickness of the second plating layer.

5. The printed circuit board according to claim 1, wherein the first plating layer and the second plating layer is constitute of a circuit and a pad.

6. The printed circuit board according to claim 1, wherein the insulating member is made of a photosensitive resin.

7. The printed circuit board according to claim 1, wherein the first plating layer and the second plating layer are alternately arranged on the top region and the bottom region around the plating via.

8. The printed circuit board according to claim 7, further comprises an insulating layer stacked on a top surface and a bottom surface of the insulating member, wherein an opening unit is formed thereon to expose pads of the first plating layer and the second plating layer.

9. A method of fabricating a printed circuit board comprising:
patterning a first insulating member;
stacking a resist pattern on the first insulating member;
plating metal material between patterns of the first insulating member and between the resist patterns;
delaminating the resist pattern; and
coating the second insulating member on the first insulating member.

10. The method of fabricating the printed circuit board power according to claim 9, wherein, a seed layer is plated on a surface of the first insulating member, and the plating step is performed by electroplating using the seed layer.

11. The method of fabricating the printed circuit board power according to claim 10, after delaminating the resist pattern, further comprises etching the seed layer exposed to an outside.

12. The method of fabricating the printed circuit board power according to claim 9, wherein in the patterning step only a predetermined period of the first insulating member is patterned and the resist pattern is formed of a first resist pattern arranged at a period patterned in the first insulating member and a second resist pattern arranged at a period which is not patterned.

13. The method of fabricating the printed circuit board power according to claim 9, wherein the first insulating member is prepared at a state to be stacked on a carrier and the carrier is removed after the second insulating member is coated.

14. The method of fabricating the printed circuit board power according to claim 9, after coating the second insulating member, further comprises
stacking insulating layers on outer layers of the first insulating member and the second insulating member; and
fabricating an opening unit to expose pads at the insulating layer.
